(19) United States
(12) Patent Application Publication
(10) Pub. No.: US 2006/0163206 A1
(43) Pub. Date: Jul. 27, 2006

(54) Novel polishing slurries and abrasive-free solutions having a multifunctional activator

(76) Inventors: Irina Belov, Zionsville, IN (US); Timothy D. Moser, Brownsburg, IN (US)

Correspondence Address: PRAXAIR, INC.;LAW DEPARTMENT - M1 557, 39 OLD RIDGEBURY ROAD, DANBURY, CT, 06810-5113, US

(21) Appl. No.: 11/335,579

(22) Filed: Jan. 20, 2006

Related U.S. Application Data
(60) Provisional application No. 60/646,481, filed on Jan. 25, 2005.

(51) Int. Cl. C09K 13/00; H01L 21/461; B44C 1/22; C23F 1/00; C03C 15/00; H01L 21/302

(52) U.S. Cl. 216/88; 252/79.1; 252/79.4; 438/692; 216/89

(57) ABSTRACT

The present invention relates to aqueous slurry/solution compositions for the Chemical Mechanical Polishing/Planarization (“CMP”) of substrates. In particular, the novel slurries/solutions of the present invention contain a multifunctional activator which provides increased copper removal rate to the aqueous polishing slurry/solution while suppressing isotropic chemical etch and dishing of copper lines.

### BACKGROUND OF THE INVENTION

1. Field of the Invention

The present invention relates to aqueous slurry/solution compositions for the Chemical Mechanical Polishing/Planarization (“CMP”) of substrates. The slurries/solutions of the present invention are particularly useful for polishing metal layers, such as copper and copper alloys, which are utilized in the process of metal interconnect formation on integrated circuit devices. The novel slurries/solutions of the present invention contain a multifunctional activator which provides increased copper removal rate to the aqueous polishing slurry/solution while suppressing isotropic chemical etch and dishing of copper lines. These novel polishing compositions provide high removal rates of copper, low chemical etch, good planarization capabilities, wide overpolish window, high stability and long shelf life.

2. Description of Related Art

The manufacturing of integrated circuits and other electronic devices require numerous complicated steps, in particular, the formation of various features onto the substrate. This involves subsequent deposition and removal of multiple layers of materials. Global planarization of topographic features is commonly utilized in the manufacture of high performance ultra-large scale integrated (“ULSI”) devices. Planarization of the surface of the substrate is a process that removes excess deposited materials used to fill the features, thus providing a planar surface for subsequent levels of metallization as well as removes unwanted surface topography and defects. Integrated circuits (IC) with small device dimensions, increased packaging density and multiple metal insulating wiring levels impose stringent planarity demands on the IC manufacturing process. Non-planarity deleteriously impacts the device yield and performance.

Dual-damascene copper patterning is the technology of choice for multilevel interconnect formation of advanced generation IC devices. In dual-damascene processing, images of both via holes and trenches are etched in a dielectric layer followed by deposition of a thin barrier layer to prevent copper diffusion into dielectric. The diffusion barrier of choice is generally a composite layer of tantalum and tantalum nitride. A thin seed layer of copper is deposited on the barrier layer and is followed by deposition of the bulk copper layer. CMP has been established as a key process step to remove the copper overburden from the damascene structures and to meet planarization requirements.

The two major topography-related concerns in the polishing of copper damascene structures are dishing of the copper lines and erosion of the field dielectric. To overcome these issues a two-step copper CMP process has been adopted. The first step is to polish and remove the bulk copper overburden; and the second is to polish and remove the tantalum nitride/tantalum barrier while planarizing the surface for further processing. The first step is carried out in a manner where the process stops upon reaching the barrier layer. The second step can be performed so as to utilize a selective slurry to remove the residual copper and the barrier, yet stop on the dielectric layer, or alternatively utilize a non-selective slurry which removes copper, barrier and dielectric at similar removal rates.

A CMP slurry effective for the removal of copper overburden must provide high polishing rate (which impacts wafer throughput), high planarization efficiency, uniformity of copper line thickness across the wafer and low copper dishing in the lines (both of which directly correlate to the interconnect resistivity). Further, it is also important that no copper residue is left on the surface after CMP that can cause electrical shortage and deterioration of device performance and yield. To ensure an absence of Cu residue overpolishing (i.e., polishing some additional time after Cu clearing) is typically performed. Thus, it is necessary for efficient copper slurry to provide wide enough processing window for overpolish, (i.e., not to cause topography deterioration through increasing dishing and erosion during overpolishing step).

Another important requirement in copper CMP processes is that the wafer surface following the CMP must be free of defects such as pits caused by copper corrosion, microscratches and particles. CMP processes face an increasing demand to reduce defects without a negative impact on production throughput. The fewer defect requirement becomes more difficult to meet with integration of low-k dielectric materials which have poor mechanical strength.

Slurries utilized for the conventional copper CMP typically contain the following components:
a) an oxidant to oxidize the copper layer and form copper oxides, hydroxides and ions;
b) a complexing agent to react with the oxidized layer and assist in the removal of polishing debris from the reaction zone;
c) a corrosion inhibitor to eliminate unwanted isotropic etch through the creation of a protective layer on copper film surface and further preventing recessed areas from chemical interaction with the slurry; and
d) abrasive particles to provide mechanical action of abrading a surface layer formed on the polished film by slurry liquid phase and thus exposing new material for chemical interaction.

Steigerwald et al.'s “Surface Layer Formation During the Chemical Mechanical Polishing of Copper Thin Films”, Mat. Res. Soc. Symp. Proc., v. 337, pp. 133-38, 1994, discloses principal chemical processes during copper CMP as surface layer formation, dissolution of mechanically abraded copper through the use of a complexing agent or an oxidizing acid and chemical acceleration of copper removal by oxidizing agents. Caprio et al. “Initial Study on Copper CMP Slurry Chemistries” Thin Solid Films, v. 266, pp. 238-44, 1995, proposed two approaches to slurry formulations in order to protect the recessed areas on the patterned wafer from undesired isotropic etch and simultaneously provide adequate planarization. The approaches include the application of passivation chemistry with neutral or basic pH or dissolution chemistry with corrosion inhibitors and acidic pH. Often the slurry for bulk copper removal is acidic in order to provide high removal rate (RR) and high removal selectivity of copper as opposed to the tantalum/tantalum nitride barriers and silicon dioxide field dielectrics.

Abrasive particles most often employed in the CMP slurries are alumina, as well as fumed or colloidal silica. Colloidal silica-based slurries that contain relatively soft, amorphous, nonagglomerated SiO₂ particles with a spherical morphology produce smooth polished surfaces with fewer defects as opposed to fumed silica-based and alumina-based slurries. On the other hand, the drawback of colloidal silica-based slurries is the reduced removal rate in comparison to fumed SiO₂ and Al₂O₃ containing slurries. As described in Hirabayashi et al. “Chemical Mechanical Polishing of Copper Using a Slurry Composed of Glycine and Hydrogen Peroxide” Proc. CMP-MIC Conf. pp. 119-23, 1996 and U.S. Pat. No. 5,575,885 CMP of copper performed with a slurry containing glycine as a complexing agent, hydrogen peroxide as an oxidizer and silica abrasive, with or without a corrosion inhibitor results in a low static etch rate and a number of defects. The removal rate reported, however, was not high enough for efficient bulk copper removal. According to Sasaki et al. (U.S. Pat. No. 5,770,095) copper slurries including glycine as a complexing agent, hydrogen peroxide as an oxidizer, BTA as a corrosion inhibitor and 5.3 weight percent (“%”) silica particles, demonstrated removal rates of 2000 Å/min. or below. Thus, in order to increase the removal rate of colloidal silica-based slurries they have to be modified so as to render them chemically aggressive.

In general, the demand for the slurries with the significantly higher chemical activity is in agreement with the most recent trend in the development of copper CMP processes: stringent requirements of achieving low dishing of copper lines with longer overpolish window call for the reduced contribution of CMP mechanical component through reduction of polishing downforce, as well as use of low-abrasive (LA) slurries and/or completely abrasive-free (AF) solutions.

In the abrasive-free approach a polishing solution interacts with copper thus creating a soft surface layer that can be removed solely by a mechanical abrasion of a polymeric pad. Enabling CMP with LA slurries and especially AF solutions provides significant advantages as compared to the conventional CMP process, such as reduced stresses and surface defectivity associated with abrasive particles, simplified post-CMP wafer cleaning, and easier slurry handling. A detailed review of the AF solutions' advantages is presented by Masanobu Hanazono et al. in “Development and Application of an Abrasive-Free Polishing Solution for Copper”, MRS bulletin, v.27, 10, 2002, pp. 772-775.

Further, in CMP with conventional slurries dishing and erosion typically increase linearly by overpolishing. At the same time, with AF solution dishing and erosion tends to change very little during overpolish. Thus, the processing window for overpolishing is wide.

However, reducing contribution of mechanical removal during CMP processes usually results in a number of drawbacks. Among them are deteriorating wafer throughput due to lower removal rates, less control of the within-wafer thickness nonuniformity (WIWNU), difficulties in initiating polish at low downforce, as well as significant increase in overpolish time required to completely clear copper and often a failure to remove Cu residue from field regions.

The above considerations regarding advantages and drawbacks of low-abrasive slurries are substantiated by the experimental data of Borst C. L. et al. presented in “Challenges and Rewards of Low-Abrasive Copper CMP: Evaluation and Integration for Single-Damascene Cu/Low-k Interconnects for the 90 nm Node”, Mat. Res. Soc. Symp. Proc., pp. 3-14, Apr. 13-15, 2004, San Francisco, Calif. The authors compared two commercially available slurries with alumina abrasive particles: conventional slurry and low-abrasive one; the slurries contain about 3 weight % and 0.5 weight % Al₂O₃, respectively. A significant decrease in RRs was observed with reduced abrasive concentration, especially at low downforce where the RR decreased from 4,000 Å/min to only 2,000 Å/min at 1 psi. However, a vast improvement in copper dishing and wide overpolish window was achieved for the LA slurry.

Kondo et al. (U.S. Pat. No. 6,561,883) discloses a polishing method for metal film polishing using an AF polishing solution including an oxidizer, a substance which renders a metal oxide water-soluble, a thickener, a corrosion inhibitor and water wherein for copper film the polishing AF solution includes hydrogen peroxide as an oxidizer, a carboxylic acid (preferably citric or malic acid), BTA as a corrosion inhibitor and polyacrylic acid as a thickener. According to Konodo et al. CMP with the disclosed polishing solution allowed for the suppression of copper film scratching, delamination, dishing and erosion. However, the copper removal rates reported (i.e., 2,000-2,500 Å/min at 3 psi downforce) are not high enough to achieve the requisite production level wafer throughput.

Kondo et al. (U.S. Pat. No. 6,562,719) discloses copper polishing performed using a polishing solution which contains hydrogen peroxide, phosphoric acid, lactic acid and an inhibitor including an anticorrosive agent, preferably imidazole or BTA, and a polymer, preferably polyacrylic acid or its salts. Reportedly the copper RRs were higher than 5000 Å/min at 3 psi downforce with etch rates as low as 10-100 Å/min and suppressed dishing and erosion. Also in “Development and Application of an Abrasive-free Polishing Solution for Copper”, MRS bulletin, v.27, 10, 2002, pp. 772-775 by Masanobu Hanazono et al., RR of 5500 Å/min at 3 psi downforce were reported with dishing of copper lines (100 μm line with 50% pattern density) equal to 500 Å. However, neither of these sources presented data on RRs at polishing downforce lower than 2 psi that is customary used on the finishing step of copper overburden removal (so-called soft-landing step) or even throughout the whole polishing process in the case of low-k dielectric material. Further, it is known in the art that AF solutions are typically slow to initiate polishing at low downforce.

Indeed, according to Enomoto et al. “Advanced Cu CMP Slurry & Spin-on Low-k for 65 nm Technology”, CAMP 9^{th} International Symposium on Chemical-Mechanical Planarization, Aug. 8-11, 2004, Lake Placid, N.Y., the above AF solutions demonstrated low RR of 400 Å/min when employed into polishing at downforce of 1.5 psi; dishing was equal 700 A for 100 μm Cu line with 50% pattern density.

Li et al (U.S. Patent Application Publication No. 2002/0182982 A1) reports difficulties with removing copper residue when using several commercially available AF and LA slurries (i.e., complete Cu clearing was achieved only with additional activation of these commercial slurries through increase in abrasive content, concentration of chelating agents, etc.).

As seen from the above description of the related art, to enable production-worthy low-downforce and LA/AF processes, copper polishing slurries/solutions are required with significantly higher chemical activity than conventional CMP slurries. While the use of more aggressive chemistries can increase RRs, it is also likely to increase copper isotropic etch and hence copper corrosion and dishing. Thus, high removal rate for LA/AF polishing composition must be accompanied by low, well controlled isotropic etch rate.

Benzotriazol (BTA) and its derivatives, imidazole, triazole, benzimidazole and its derivatives are known in the art as corrosion inhibitors for copper and copper-based alloys that efficiently suppress isotropic etching, with BTA being a corrosion inhibitor of choice (See Brusic V et al., “Copper corrosion With and Without Inhibitors”,—J. Electrochem. Soc., vol. 138, No. 8, pp. 2253-2259, 1991).

It is known in the art that although chemical etch is suppressed by BTA addition, typically removal rate also is being reduced by increasing BTA concentration. Thus, an adverse effect of BTA on copper RR presents constraints on the polishing composition's capability to balance high enough RRs with low chemical etch rate. These constraints become especially significant in LA/AF slurries where RRs are reduced by low concentration/or complete elimination of abrasive particles.

To overcome the disadvantages associated with the art related polishing slurries/solutions and to meet the polishing/planarization requirements, the present invention provides compositions of low-abrasive/abrasive-free solutions which include a multifunctional polishing activator.

One object of the invention is to provide slurry/solution composition that is particularly useful in the processing of copper interconnect damascene structure.

Another object of the invention is to provide polishing compositions, wherein employment of a multifunctional activator results in a significant increase in copper removal rates thereby enabling a low-downforce CMP process.

It is yet another object of the invention to provide polishing compositions, wherein the presence of the multifunctional activator results in a significant increase in the rates of copper removal thus enabling efficient CMP processes using slurries with low content of abrasive particles and/or completely abrasive-free polishing solutions.

A further object of the invention to provide a composition of polishing slurries/solutions with low isotropic etch rate of copper film and high selectivity toward tantalum nitride/tantalum barrier material removal.

It is yet a further object of the invention, to provide high rates of copper removal; similar to those provided by alumina-based slurries while preserving advantages of using colloidal silica abrasive (i.e., low roughness and reduced defects in the polished surface) in low concentration.

Other objects and advantages of the invention will become apparent to one skilled in the art on a review of the specification and figures appended hereto.

### SUMMARY OF THE INVENTION

The foregoing objectives are met by the aqueous slurry/solution composition of the present invention.

According to a first aspect of the invention, an aqueous slurry/solution composition for polishing/planarization of a metal film is provided. The composition includes a multifunctional activator, a corrosion inhibitor, a complexing agent capable of forming water-soluble complexes with ions of a polished metal and an oxidizer. The composition of the present invention may be abrasive-free or may contain abrasive particles.

According to another aspect of the invention, a multifunctional activator compound selected from the group of diazines and their derivatives, preferably from the group of pyrimidines and their derivatives, more preferably from the group of aminopyrimidine and its derivatives for polishing slurries/solution compositions is provided.

According to yet another aspect of the invention, an aqueous slurry/solution composition for the removal of copper overburden through chemical-mechanical polishing/planarization is provided, wherein said composition demonstrates high removal rates of copper, low chemical etch, good planarization capabilities, wide overpolish window, high selectivity toward tantalum nitride/tantalum barrier material removal, good stability and long shelf life. The aqueous slurry/solution composition of the present invention includes a multifunctional activator, particularly 2-aminopyrimidine, wherein employing the multifunctional activator provides increase of copper removal rate without increasing chemical etch rate.

According to yet another aspect of the invention, a polishing slurry/solution composition is provided, wherein presence of the multifunctional activator results in increase in the rates of copper removal, thereby enabling efficient CMP processes using slurries with low content of abrasive particles or completely abrasive-free polishing solutions.

According to still yet another aspect of the invention, polishing slurry/solution composition is provided, wherein the presence of the multifunctional activator results in increase in the rates of copper removal thereby enabling low-downforce CMP processes.

According to yet another aspect of the invention, a polishing slurry/solution composition is provided with low isotropic etch rate of copper film and high selectivity toward tantalum nitride/tantalum barrier material removal.

According to still yet another aspect of the invention, a slurry composition is provided wherein the slurry demonstrates high rates of copper removal while preserving advantages of using colloidal silica abrasive in low concentration.

### BRIEF DESCRIPTION OF THE FIGURES

The invention will be better understood by reference to the following Figures.

FIG. 1 illustrates bulk copper removal acceleration in the presence of 2-aminopyrimidine (2-AMPM) activator for the slurry compositions containing various amount of glycine; the slurries contain the same amount of BTA equal 0.054 weight % and have pH=3.2.

FIG. 2 depicts copper removal rates for the slurry compositions in 2-AMPM—NH₄EDTA system versus concentration of NH₄EDTA; the slurries contain 0.054 weight % BTA and have pH=3.2.

FIG. 3 exhibits copper removal rates as well as Zeta potentials of the colloidal silica particles for the slurries in 2-AMPM—NH₄EDTA system versus concentration of 2-AMPM; the slurries contain 0.054 weight % BTA and have pH=3.2.

FIG. 4 demonstrates a synergistic effect of 2-AMPM and BTA on bulk Cu RRs for the slurries in 2-AMPM—glycine system; the slurries contain the same amount of glycine equal 1.0 weight % and have pH=3.2.

### DETAILED DESCRIPTION OF THE INVENTION

The present invention relates to a novel polishing slurry/solution composition and is particularly useful in the chemical mechanical polishing/planarization (CMP) of substrates and metal layers of multilevel interconnects.

In particular, the present invention provides an aqueous slurry/solution composition for polishing/planarization of a metal film. The aqueous polishing slurry/solution composition includes an activator, a corrosion inhibitor, a complexing agent capable of forming water-soluble complexes with ions of a polished metal and an oxidizer. The composition of the present invention may be an abrasive-free solution or may contain abrasive particles in low concentrations. The composition has been found to have particular applicability in the CMP of copper due to the high removal rates of copper, low chemical etch, good planarization capabilities, wide overpolish window, high selectivity toward tantalum nitride/tantalum barrier material removal, good stability and long shelf life.

The present invention is founded on the discovered ability of diazines and their derivatives, preferably pyrimidines and their derivatives, and more preferably aminopyrimidine and its derivatives, to accelerate copper polishing removal while suppressing unwanted isotropic chemical etch (i.e. to act as a multifunctional activator).

The multifunctional activator of the present invention when employed in metal CMP polishing slurries/solutions allows to significantly increase removal rate (RR) of copper without increasing chemical etch rate (ChemER). This activator is a compound selected from the group of diazines and diazine derivatives—aromatic heterocyclic molecules having two nitrogen atoms in the aromatic ring.

Three diazine ring systems—pyridazine, pyrimidine and pyrazine—differ by nitrogen atom position in the aromatic ring, as represented by structures (1) below. Structural derivatives of diazines are formed with various substituting groups. Diazine compounds suitable for use in the invention are compounds having a pyridazine, pyrimidine or pyrazine ring system in their molecular structure, 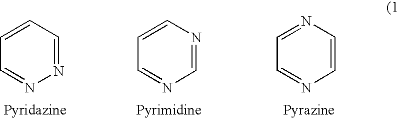
such as, for examples, pyrimidine, methylpyrimidines, aminopyrimidines, aminouracils, pyradazine, pyrazine, pyrazinecarboxamide, benzodiazines such as phthalazine, cinnoline and quinoxaline, and the like.

It has been found that this multifunctional activator compound preferably belongs to the group of pyrimidines and their derivatives, more preferably to the group of aminopyrimidines, such as 2-aminopyrimidine, 4-aminopyrimidine, 2,4-diaminopyrimidine, 4,6-diaminopyrimidine, 2,4,6-triaminopyrimidine, 4,5,6-triaminopyrimidine and the like.

In the present invention 2-aminopyrimidine (2-AMPM)—a compound with pyrimidine ring system and one substituting NH₂ group—was found to be particularly efficient as an activator when used as a component of polishing slurry for copper removal. It has been found that the addition of 2-AMPM in the amount of as low as 0.1-0.5 weight % results in 2-4 times increase in bulk Cu RRs while preserving low ChemER, wherein ratio of RR:ChemER is not less than 100.

This behavior is unexpected as it is known in the art that increase in the chemical activity of CMP slurries is usually achieved through accelerated copper dissolution by decreasing pH or increasing concentration of a complexing agent (i.e., by accelerated formation of water-soluble copper species). Thus, removal rate activation is typically accompanied by the increasing isotropic copper etching.

The unique ability of diazine derivatives, specifically aminopyrimidine to increase copper RRs without any negative impact of increased ChemER means that the activator performs several functions, such as formation of water-soluble complexes with copper and moving copper away from the polished surface, while simultaneously forming a protective layer on a copper surface to prevent its corrosion.

Another property of the multifunctional activator of the present invention is its ability to eliminate a well known adverse effect of corrosion inhibitors, particularly BTA, on copper removal rates. Moreover, rather surprisingly Cu RR of the 2-AMPM containing slurries/solutions actually increases with increasing BTA concentration. The multifunctional activator enables polishing compositions of the present invention to balance high copper removal rate with low chemical etch. The unexpected effect of increasing RRs of copper of the 2-AMPM containing slurries/solutions with increasing BTA concentration indicates that a synergistic action takes place between 2-AMPM and BTA.

Without being bound by any particular theory, it is believed that the unique multifunctional action of diazine derivatives, particularly aminopyrimidine derivatives, and specifically 2-AMPM, is a result of its molecular structure (2) providing multiple bonding 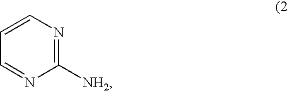
sides for coordinating both Cu(I) and Cu(II) ions: 2-AMPM can coordinate as a monodentate ligand via a pyrimidine ring N atom or an amino N atom, as a bidentate ligand chelating through two pyrimidine ring N atoms or through a ring N atom and amino N atom, and also can form Cu—pyrimidine ring π-complex.

According to Allan et al. “The Preparation and Thermal Analysis Studies on Some First Row Transitional Metal Complexes of 2-Aminopyrimidine”, J. Therm. Anal., v.22, pp. 3-12, 1981, coordination Cu(II)-2-AMPM takes place through one of the nitrogen atoms in the pyrimidine ring and the N atom of the amine group. Lumme et al. “Studies on Coordination Compounds—VIII. Synthesis, Structural, Magnetic, Spectral and Thermal Properties of Some Cobalt(II), Nickel(II) and Copper(II) Complexes of 2-Aminopyrimidine”,—Polyhedron, v.14, No. 12, pp. 1553-1563, 1995 determined that Cu(II)-2-AMPM coordination happened through one ring nitrogen atom. The similar conclusions of one of pyrimidine ring nitrogen being involved in 2-AMPM bonding with Cu(II), probably as bridging group, was done by Singh et al. See “Spectral and Magnetic Properties of Copper(II) Complexes with 2-Aminopyrimidine and 2-Amino-4-methylpyrimidine”, J. Indian Chem. Soc., v. LXIV, pp. 359-360, 1987.

Thus, it is believed in the present invention that the ability of 2-AMPM to accelerate copper removal is caused by formation of water-soluble Cu(II)—2-AMPM complexes, probably through bonding of one of the ring nitrogen atom.

Pyrimidine derivatives are also known to form complexes with the copper surface. It was found by Quang Miao et al. (“Estimation of Coordination Complex Structure of O—Cu(I)-2-aminopyrimidine on a Copper Surface Using X-ray Photoelectron Spectroscopy”, Appl. Surf. Sci., v.171, pp. 49-56, 2001) that 2-AMPM formed complexes with the oxidized copper surface, said surface complexes of Cu(I) [O—Cu(I)-2-AMPM] being formed by pyrimidine ring π complexing with Cu(I).

Although not wanting to be bound by any particular theory, it is believed in the present invention that the ability of the pyrimidine derivatives, specifically 2-AMPM, to form Cu(I)-2-AMPM complexes results in building a protective layer on the copper surface which in turn provides low chemical etch rate of the polishing slurries/solutions containing the 2-AMPM activator. As a result, self-assembled O—Cu(I)-2-AMPM films might be formed on the copper surface, similar to the known phenomenon of O—Cu(I)—BTA film self-assembly. This theory explains the observed unusual synergistic action of 2-AMPM and BTA in the slurries of the present invention. Because both BTA and 2-AMPM are capable of forming a surface film, it may be possible that they actually form a mixed film where both BTA and 2-AMPM form complexes with Cu(I)of oxidized copper surface via π-coupling of their aromatic rings.

The content of the activator, specifically 2-AMPM, in the slurry/solution ranges from 0.01-10.0 weight percent, preferably about 0.05-5.0 weight percent, and most preferably about 0.1-2.0 weight percent. The ranges selected are dependent on the requirement to reach a favorable balance between removal rate and static etch rate. If the composition contains abrasive particles, particularly colloidal silica particles, colloidal stability of the slurry (as characterized by Zeta potential value) should be also taken into consideration when choosing content of 2-AMPM activator.

While BTA is a preferred corrosion inhibitor employed in the slurries/solutions of the present invention, other corrosion inhibitors known in the art, such as imidazole, triazole, benzimidazole, derivatives and mixtures thereof, are suitable alternatives. The amount of BTA ranges from about 0.01-1.0 weight percent, preferably about 0.03-0.60 weight percent, and most preferably about 0.05-0.50 weight percent. The optimum BTA content is determined based on the criteria of obtaining high RR:ChemER ratio. Preferably, the ratio is higher than 100:1, and more preferably higher than 150:1.

Another component of the slurry/solution composition is the complexing agent. The complexing agent can be selected, for example, from among carboxylic acids (e.g., acetic, citric, oxalic, succinic, lactic, tartaric, etc.) and their salts, as well as aminoacids (e.g., glycine, alanine, glutamine, serine, histidine, etc.), amidosulfuric acids, their derivatives and salts. In one embodiment, the complexing agent utilized is NH₄EDTA—diammonium salt of ethylenediaminetetraacetic acid (EDTA); other EDTA salts can also be used. In another embodiment, glycine is employed as a complexing agent. The content thereof in the slurry ranges from 0.05-5.0 weight percent, preferably about 0.1-3.0 weight percent, and most preferably about 0.2-2.0 weight percent. The ranges selected are dependent on the requirement to reach a favorable balance between removal rate and chemical etch rate. In other words, the complexing agent's concentration must be enough to provide high copper removal rate through efficient complexing action on the oxidized copper layer. However, an excess concentration of the complexing agent might cause undesirable increase of isotropic copper etch.

Another component generally added to the slurry composition is the oxidizer. Although hydrogen peroxide is preferably utilized, other oxidizers can be selected, for example, from among inorganic peroxy compounds and their salts, organic peroxides, compounds containing an element in the highest oxidation state, and combinations thereof. In a preferred embodiment, hydrogen peroxide is added to the slurry shortly before employment in the CMP process. The slurry/solution of the present invention when mixed with hydrogen peroxide has a pot life (i.e. time interval during which no noticeable decrease in the H₂O₂ concentration and/or RRs is observed) of at least seventy-two hours, and often more than two hundred hours. The amount of hydrogen peroxide added to the slurry is determined by the requirement necessary to maintain high removal rates of copper, on the one hand, and a low static etch on the other. Preferably the amount of hydrogen peroxide added to the slurry composition ranges from about 0.1-20 volume percent, preferably about 0.5-15 volume percent, and most preferably about 1.0-10.0 volume percent.

The compositions of the present invention can be abrasive-free or contain abrasive particles. Abrasive particles of various types known in the art are suitable, such as colloidal and fumed silica, alumina, cerium dioxide, mixtures thereof and the like. However, silica particles are preferred, with colloidal silica particles being more preferable due to their spherical morphology and ability to form nonagglomerated monoparticles under appropriate conditions. As discussed previously, the slurries incorporating these particles yield a reduced number of defects and a lower surface roughness of the polished film, as opposed to irregularly shaped fumed silica particles. Colloidal silica particles may be prepared by methods known in the art such as ion-exchange of silicic acid salt, or by sol-gel technique (e.g., hydrolysis or condensation of a metal alkoxide, or peptization of precipitated hydrated silicon oxide, etc.).

Aluminate-modified colloidal silica has been found to be the most preferred abrasive particles for the slurries of the present invention. As disclosed by Belov (U.S. patent application No. 10/935,420), which is incorporated herein by reference in its entirety, an aqueous slurry composition which comprises silica abrasive particles, wherein the abrasive particles are anionically modified/doped with metallate anions, particularly with aluminate ions, provides high negative surface charge to the particles thereby enhancing the stability of the slurry, especially at acidic pH, as compared to unmodified colloidal silica.

The average particle size of the silica is about 10-200 nm, preferably about 20-140 nm, and most preferably about 40-100 nm. It will be understood by those skilled in the art that the term “particle size” as utilized herein, refers to the average diameter of particles as measured by standard particle sizing instruments and methods, such as dynamic light scattering techniques, laser diffusion diffraction techniques, ultracentrifuge analysis techniques, etc. In the event, the average particle size is less than 10 nm it is not possible to obtain a slurry composition with adequately high removal rate and planarization efficiency. On the other hand, when the particle size is larger than 200 nm, the slurry composition will increase the number of defects and surface roughness obtained on the polished metal film.

The content of silica particles in the aqueous slurry of the present invention is in a range of about 0.01-30 weight percent, preferably 0.02-10 weight percent, depending on the type of material to be polished. In the slurry for copper CMP, the content of silicon dioxide particles ranges from about 0.02-5.0 weight percent, preferably 0.03-3.0 weight percent, most preferably being in the range of 0.05-2.0 weight percent. If the silicon dioxide content is less than about 0.05 weight percent, the removal rate of copper film is decreased. On the other hand, the upper limit of silicon dioxide content has been dictated by the current trend of using low-abrasive slurries for copper removal to reduce the number of defects on the polished film surface. The preferable upper limit of about 2.0 weight percent has been established based on the removal rates; further increases in silicon dioxide content has been observed not to be particularly beneficial.

The slurries/solutions of the present invention preferably have a pH below 6.0, more preferably below 5.0, and most preferably below 4.0. In the event that the pH of the slurry requires adjustment, acids may be added to the composition. Some of the strong acids that may be selected for this purpose include sulfuric acid, nitric acid, hydrochloric acid and the like. Preferably, the acid is orthophosphoric acid (H₃PO₄) because this acid is known to act as a stabilizer for hydrogen peroxide oxidizer. Thus, employing H₃PO₄ for pH adjustment has an additional benefit of enhancing pot life of the slurry/solution after mixing with hydrogen peroxide.

On the other hand, if an alkali is needed to adjust the pH to a more basic state, alkali metal hydroxides such as potassium hydroxide, sodium hydroxide and ammonia may be utilized. Further, organic bases such as triethanolamine, tetramethylammonium hydroxide (TMAH) and the like may be employed as well.

The slurry/solution may also contain additional components such as biocides, pH buffers, surface-active additives such as wetting agents and the like, additives to control foaming, viscosity modifiers, etc.

Biocides, for example, prevent growth of microorganisms such as bacteria, and fungus. Growth of microorganisms is known as one of the major contamination sources and of great concern in IC manufacturing. Once on the device, bacteria act as particulate contamination. Certain slurry/solution components such as aminoacids (e.g., glycine) are particularly susceptible to microbial growth. To prevent the microorganism growth, in an embodiment of the present invention, a biocide in an amount of 50-1000 ppm can be introduced in the composition. Examples of useful biocides include Dow Chemical Company's BIOBAN™ and Troy Corporation's MERGAL K12N™.

The aqueous slurry/solution compositions of the present invention will be further described in detail with reference to the following examples, which are, however, not to be construed as limiting the invention.

### EXAMPLES

The following slurry compositions of Examples 1-21 were prepared and utilized to polish 8″ blanket copper wafers (15K Angstrom Electroplated Cu film, annealed) or 2″ coupons cut from these wafers. In addition, 8″ patterned wafers (854 MIT mask, 3K trench depth/10K Cu total thickness and 6K trench depth/11K Cu total thickness) were polished to determine planarization capabilities and dishing/overpolish behavior of the slurries/solutions of Examples 1-21. Polishing tests were carried out on a IPEC472 CMP polisher at a downforce in the range from 1.5 to 3.5 psi, (80 rpm platen rotation speed, 40 rpm wafer carrier rotation speed, 150-200 ml/min slurry flow rate), as well as on a bench-top polisher, Model UMT-2, Center for Tribology, Inc. The polishing parameters for the bench-top polisher (3.0 psi downforce, 140 rpm platen speed, 135 rpm carrier speed) were chosen to match the removal rate obtained on the IPEC472 polisher. IC1000™ stacked pad with Suba IV™ subpad by Rodel Co. Inc., was utilized on both polishing tools. The pad had been conditioned in-situ.

The polishing rate (Å/min.) was calculated as the initial thickness of each film having subtracted therefrom after-polishing film thickness and divided by polishing time. The average from at least three polishing tests was used to calculate removal rate. Copper film thickness data had been obtained by RS 75 sheet resistance measuring tool, KLA Tencor, Inc.; 81 point diameter scan at 5 mm edge exclusion was used for metrology. Topography measurements on patterned wafers before and after polishing tests have been performed using P2 tool, from KLA Tencor, Inc.

Chemical etch rate (ChemER) of copper in the slurries/solutions of the Examples 1-21 were measured as follows. Three 2″ blanket wafer coupons were immersed in 50 ml of a slurry/solution and maintained under stirring for 5 min. The liquid was collected and a concentration of chemically dissolved copper was determined from the transmittance spectrum in the wavelength range from 400 to 800 nm using UV-2401 spectrometer, Schimadzy Scientific Instruments, Inc.

Average particle size (Zav) of colloidal silica particles was measured by HPPS, Malvern Instruments Co.

Zeta potential measurements (one-point data at fixed pH as well as Zeta-pH curves) for colloidal particles in the slurries were performed on ZetaSizer Nano-Z, Malvern Instruments Co. Standard 1N, 0.5N and 0.1N solutions of HNO₃ and KOH were used for pH titration.

Slurry stability/shelf life was in addition tested by measuring Large Particle Count (LPC)—number of oversized colloidal particles (i.e., larger than 1.5 micron) which grow with time. The less LPC changes with slurry storage time, the more stable are the colloidal silicon dioxide particles in the slurry. An AccuSizer Model 780 instrument from Particle Sizing Systems, Inc., was utilized to measure LPC. The results were calculated as an average from 5 tests per each sample.

### Comparative Example 1 and Example 2

In examples 1-2, corresponding slurries A and B, the slurry A has been prepared by adding 1.74 g BTA (from Sigma-Aldrich) and 32 g glycine (Sigma-Aldrich) into 3,120 g deionized H₂O. The resulting solution contained 0.054 weight % BTA and 1.0 weight % glycine. A diluted aqueous solution (from 7 to 30 weight percent) of H₃PO₄ was employed to adjust the pH to about 3.2. Thereafter, 106.6 g of aluminate-modified colloidal silica (as 30 weight percent water dispersion) having a particle size (Zav) of 50 nm was added to the solution while mixing; the silica content in the slurry was equal to 1.0 weight %. The slurry was then mixed for about 0.5 hours, and 20 ml of H₂O₂ (as 34 weight percent water solution) was added so that the content of H₂O₂ obtained was 2 volume percent.

The slurry B has been prepared in the same manner as slurry A, except that in addition 4 g of 2-AMPM (Sigma-Aldrich) equal to 0.125 weight % content has been added in the slurry. The slurry B was then mixed with 20 ml of H₂O₂ (as 34 weight percent water solution), so that the content of H₂O₂ was 2 volume percent.

The slurries A and B were then utilized to perform the above-described polishing tests on the bench-top polisher, as well as to measure chemical etch rate. Removal rates of the copper film for the slurries A and B were found to be 5,800 Å/min and 11,100 Å/min, respectively. RR:ChemER ratio was found to be equal to 60 and 105 for the slurries A and B, respectively. Thus addition of 0.125 weight % of 2-AMPM resulted in about 2 times increase in the RR accompanied by the significant increase in the ratio of removal and chemical etch rates.

Slurry B was also stored at 50° C. for up to six weeks to test its stability/shelf life; increased storage temperature provides accelerated aging thus making this storage time equal to about 6 months storage at room temperature. Data on colloidal particle size Zav, Zeta potential and LPC for particles larger than 1.5 microns are presented in Table 1. As seen from these data, very minor changes of all tested characteristics of the slurry B were observed during the above storage period thus indicating good stability and sufficient shelf life of the slurries containing 2-AMPM activator.

TABLE 1
Stability and Shelf Life at 50° C. of Slurry B

| Storage | | Zeta | |
|---|---|---|---|
| period | Zav, nm | potential, mV | LPC, >1.5 μm |
| As prepared | 50 | −15 | 1,400 |
| 2 weeks | 50 | −15 | 1,600 |
| 6 weeks | 49 | −14 | 2,800 |

### Comparative Examples 3 and 5 and Examples 4 and 6

In example 3, corresponding slurry C, was prepared in the same manner as the slurry A of Example 1, except that the amount of glycine added was 16 g, which is equal to 0.5 weight % content.

In example 4, corresponding slurry D, was prepared in the same manner as the slurry B of Example 2, except that the amount of glycine added was 16 g, which is equal to 0.5 weight % content.

In example 5, corresponding slurry E, was prepared in the same manner as the slurry A of Example 1, except that no glycine was added in the process of the slurry preparation.

In example 6, corresponding slurry F, was prepared in the same manner as the slurry B of Example 2, except that no glycine was added in the process of the slurry preparation.

The pH of the slurries C-F of Examples 2-6 was equal to pH=3.2, the content of aluminate-modified colloidal silica in the slurries C-F was equal to 1.0 weight %. The slurries were then mixed with 20 ml of H₂O₂ (as 34 weight percent water solution), so that the content of H₂O₂ was 2 volume percent.

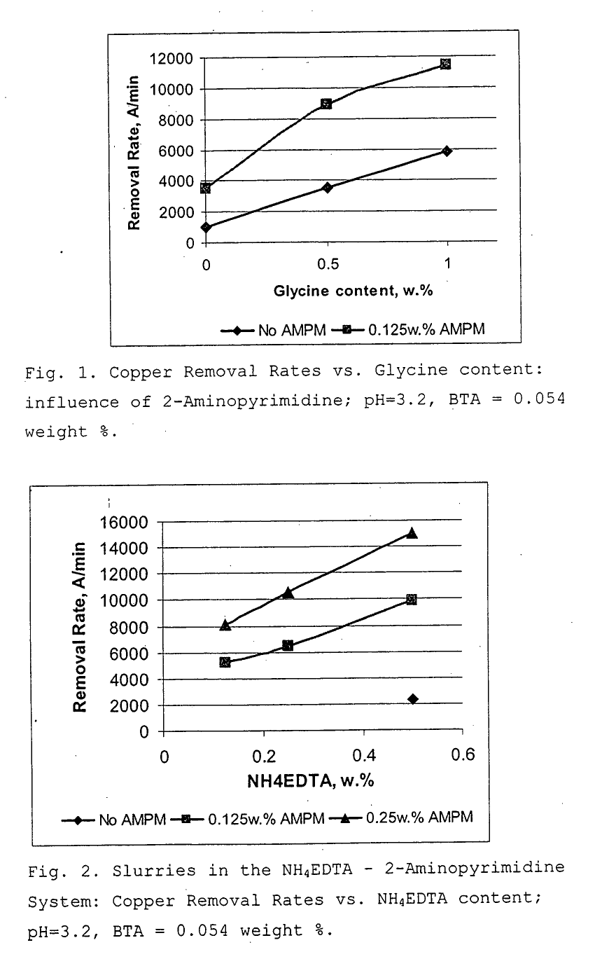

The slurries C-F of Examples 2-6 were then utilized to perform the above-described polishing tests on the bench-top polisher, as well as to measure chemical etch rate and Zeta potential. The results are tabulated in Table 2, below and graphically presented in FIG. 1, together with the results for the slurries A-B of the Examples 1-2.

The presented results demonstrate that addition of 2-AMPM in the amount as low as 0.125 weight % leads to the significant acceleration in the copper removal, while practically not increasing the chemical etch, thus causing a desirable effect of increasing RR:ChemER ratio.

TABLE 2
Low-abrasive Copper Slurries Containing 2-Aminopyrimidine

| Example/ | Cu RR*, | Chem ER, | RR: | Zeta, |
|---|---|---|---|---|
| Slurry | A/min | A/min | ChemER | mV |
| Example 1/A | 5800 | 110 | 60 | −22 |
| (Comparative) | | | | |
| Example 2/B | 11100 | 100 | 105 | −15 |
| Example 3/C | 3400 | 60 | 57 | −31 |
| (Comparative) | | | | |
| Example 4/D | 8800 | 60 | 150 | −17 |
| Example 5/E | 1200 | 20 | 60 | −24 |
| (Comparative) | | | | |
| Example 6/F | 3600 | 30 | 120 | −18 |

Another positive effect of 2-AMPM is that its presence allows to achieve high enough RRs while employing lower content of glycine, (i.e. preserving low chemical etch rates of the slurry/solution).

### Comparative Example 7 and Example 8

In examples 7-8, corresponding slurries G and H, the slurry G has been prepared by adding 1.74 g BTA (from Sigma-Aldrich) and 16 g of diammonium salt of ethylenediaminetetraacetic acid (NH₄EDTA) from Sigma-Aldrich into 3,120 g deionized H₂O. The resulting solution contained 0.054 weight % BTA and 0.5 weight % NH₄EDTA. A diluted aqueous solution of H₃PO₄ was employed to adjust the pH to about 3.2. Thereafter, 106.6 g of aluminate-modified colloidal silica (as 30 weight percent water dispersion) having a particle size (Zav) of 50 nm was added to the solution while mixing; the silica content in the slurry was equal to 1.0 weight %. The slurry was then mixed for about 0.5 hours and 20 ml of H₂O₂ (as 34 weight percent water solution) was added so that the content of H₂O₂ reached 2 volume percent.

The slurry H has been prepared in the same manner as slurry G, except than in addition 4 g of 2-AMPM (Sigma-Aldrich) equal to 0.125 weight % content has been added in the slurry. The slurry was then mixed with 20 ml of H₂O₂ (as 34 weight percent water solution), so that the content of H₂O₂ reached 2 volume percent.

The slurries G and H were then utilized to perform the above-described polishing tests on the bench-top polisher, as well as to measure chemical etch rate. Removal rates of the copper film for the slurries G and H were found to be 2300 Å/min and 9900 Å/min, respectively. RR:ChemER ratio was found to be equal to 20 and 110 for the slurries G and H, respectively. Therefore, the addition of 0.125 weight % of 2-AMPM resulted in about 4 times increase in the RR accompanied by the drastic increase in the ratio of removal and isotropic etch rates.

### Examples 9-14

In examples 9-14, corresponding slurries I-N, the slurries have been prepared by adding 1.74 g BTA and NH₄EDTA in the amount varying from 4 g to 16 g into 3,120 g deionized H₂O. The resulting solution contained 0.054 weight % BTA and from 0.125 to 0.5 weight % NH₄EDTA. 2-AMPM was then added in the solution in the amount varying from 2 g to 8 g, so that the resulting solution contained from 0.075 to 0.25 weight % of 2-AMPM. A diluted aqueous solution of H₃PO₄ was employed to adjust the pH of the solutions to about 3.2. Thereafter, 106.6 g of aluminate-modified colloidal silica (as 30 weight percent water dispersion) having a particle size (Zav) of 50 nm was added to the solution while mixing; the silica content in the slurry was equal to 1.0 weight %. The slurry was then mixed for about 0.5 hours.

The concentrations of NH₄EDTA and 2-AMPM for the prepared slurries, together with the slurries G and H of the Examples 7-8 are summarized in the Table 3.

Each of the slurries was then mixed with 20 ml of H₂O₂ (as 34 weight percent water solution) so that the content of H₂O₂ was 2 volume percent.

The slurries I through N were then utilized to perform the above-described polishing tests on the bench-top polisher, as well as to measure chemical etch rate and Zeta potential.

TABLE 3
Low-abrasive Copper Slurries Containing 2-Aminopyrimidine

| | | NH₄EDTA | AMPM |
|---|---|---|---|
| | Slurry | weight % | Weight % |
| Example 7 | G | 0.5 | 0 |
| (Comparative) | | | |
| Example 8 | H | 0.5 | 0.125 |
| Example 9 | I | 0.5 | 0.075 |
| Example 10 | J | 0.5 | 0.25 |
| Example 11 | K | 0.25 | 0.125 |
| Example 12 | L | 0.25 | 0.25 |
| Example 13 | M | 0.125 | 0.125 |
| Example 14 | N | 0.125 | 0.25 |

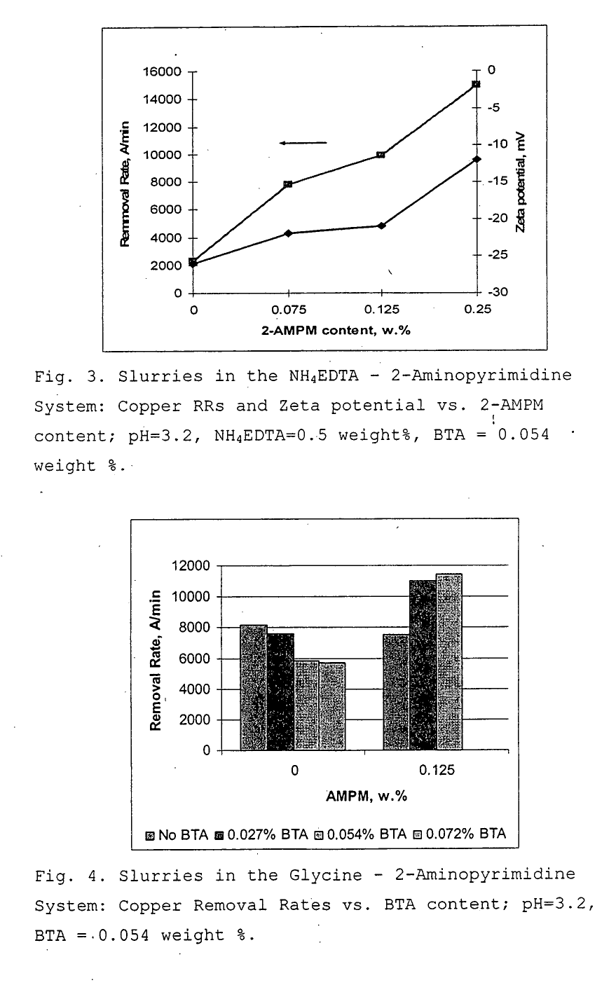

FIG. 2 presents copper RRs for the slurries G-N of Table 2. As seen from these data, the effect of acceleration of copper removal in the presence of 2-AMPM was observed at different concentrations of NH₄EDTA. FIG. 3 presents copper RRs and Zeta potential values for slurries G, H, I and J versus concentration of the 2-AMPM activator; all these slurries contain the same amount of NH₄EDTA (equal to 0.5 weight %). As seen from these data, addition of the multifunctional activator in the amount as low as 0.075 weight % resulted in about four time increase in the RR; further increase in copper RRs due to increasing concentration of 2-AMPM was observed. The increase in the RRs was not accompanied with any change in the chemical etch rate (i.e., the ChemER was practically constant and equal to about 150 Å/min).

It is also seen from FIG. 3 that Zeta potential values changed from −25 mV to −12 mV for the slurries G and J, respectively (i.e., with increase in 2-AMPM content up to 0.25 weight %). Those skilled in the art will recognize the Zeta potential as a measure of the electrostatic interaction between colloidal particles to predict the stability of the colloidal dispersion (i.e., the higher is absolute magnitude of the Zeta potential, more stable a slurry is). If the Zeta potential is too small (i.e., less than about 10-15 mV in absolute magnitude), the particles will begin to agglomerate in time. This agglomeration and growth of oversized particles leads to a deterioration of the slurry's performance in a CMP process, and in turn leads to a shortened slurry shelf life and increased defects on the film polished upon use. Thus, it is highly desirable to provide a slurry wherein the silica particles have a Zeta potential more negative than −10 mV, and preferably, more negative than −15 mV. Therefore, in the slurries containing silica abrasive particles concentration of 2-AMPM activator is limited by the requirement to maintain high enough absolute value of the Zeta potential. However, this limitation is removed for the abrasive-free solutions where colloidal stability is of no concern.

### Examples 15-19

In examples 15-16, with the purpose of characterizing corrosion inhibiting properties of 2-AMPM, corresponding slurries O and P were prepared without BTA. In examples 17-19, to demonstrate the synergy between BTA and 2-AMPM, corresponding slurries R, S and T were prepared with various BTA and 2-AMPM content.

The slurry O has been prepared by adding 32 g glycine into 3,120 g deionized H₂O; the resulting solution contained 1.0 weight % glycine. A diluted aqueous solution of H₃PO₄ was employed to adjust the pH to about 3.2. Thereafter, 106.6 g of aluminate-modified colloidal silica (as 30 weight percent water dispersion) having a particle size (Zav) of 82 nm was added to the solution while mixing; the silica content in the slurry was equal to 1.0 weight %. The slurries R and S have been prepared similar to the slurry O, except of an addition of 0.87 g BTA into the slurry R and 2.32 g BTA into the slurry S. As a result, the content of BTA in the slurries R and S was equal to 0.027 and 0.072 weight %, respectively. The slurry P has been prepared in the same manner as slurry O, except that in addition 4 g of 2-AMPM equal to 0.125 weight % content has been added in the slurry. The slurry T has been prepared similar to the slurry P, except of 0.87 g BTA was added, equal to 0.027 weight % content.

The slurries were then mixed for about 0.5 hours, and 20 ml of H₂O₂ (as 34 weight percent water solution) was added into each slurry so that the content of H₂O₂ was 2 volume percent.

The slurries O and P were then utilized to perform the above-described chemical etch rate test. ChemER equal to 1200 A/min and 750 A/min were found for the slurries O and P, respectively. Thus 2-AMPM demonstrates corrosion inhibiting behavior toward copper, however inhibition efficiency is significantly lower than that of BTA.

The slurries O through T were utilized to perform the above-described polishing tests on the bench-top polisher; copper RRs vs. BTA content in the 2-AMPM—glycine system are presented in FIG. 4.

As seen from FIG. 4, for the slurries not containing 2-AMPM increase in the BTA concentration resulted, as expected, in decreasing bulk copper RRs. At the same time, for the slurries that contained 2-AMPM copper RR unexpectedly increased with increasing BTA concentration, therefore, indicating on the existence of synergistic action between BTA and 2-AMPM multifunctional activator.

### Example 20 and Comparative Example 21

In Examples 20-21, corresponding abrasive-free (AF) solutions Q and R were prepared and tested to determine the influence of the multifunctional activator on the behavior of the AF solutions during the CMP process step of copper clearing and overpolishing.

Solution Q contained 2-AMPM and was prepared by adding 3.5 g BTA, 8 g glycine and 8 g 2-AMPM into 3,120 g deionized H₂O. The resulting solution contained 0.108 weight % BTA, 0.25 weight % each 2-AMPM and glycine. A diluted aqueous solution (from 7 to 30 weight percent) of H₃PO₄ was employed to adjust the pH to about 3.5. Then 1.25 g of the biocide Mergal™ K12N (Troy Corp.) was added to the solution while mixing; the content of biocide was equal to about 400 ppm. The solution was then mixed for about 0.5 hours, and 20 ml of H₂O₂ (as 34 weight percent water solution) was added so that the content of H₂O₂ was 2 volume percent.

Solution R did not contain 2-AMPM and was prepared by adding 1.74 g BTA and 32 g glycine into 3,120 g deionized H₂O. The resulting solution contained 0.054 weight % BTA and 1.0 weight % glycine. A diluted aqueous solution (from 7 to 30 weight percent) of H₃PO₄ was employed to adjust the pH to about 4.0. Then 1.25 g of the biocide Mergal™ K12N (Troy Corp.) was added to the solution while mixing; the content of biocide was equal to about 400 ppm. The solution was then mixed for about 0.5 hours, and 20 ml of H₂O₂ (as 34 weight percent water solution) was added so that the content of H₂O₂ was 2 volume percent.

Solutions Q and R were used to perform above-described polishing tests for 8″ blanket and patterned wafers; the results are presented in Table 4.

TABLE 4
Abrasive-free Solutions: Influence of 2-AMPM Activator
on Dishing of 100 μm Copper Line (854 MIT pattern
with 2000 Å copper remaining for clearing, IPEC
472, 80 rpm platen speed, 150 mL/min flow rate)

| | Cu RR, Å/min | Cu RR, Å/min | Dishing, | Dishing, 50% |
|---|---|---|---|---|
| Solution | (DF = 1.5 psi) | (DF = 2.5 psi) | clearing | overpolish |
| Q | 2700 | 3200 | 450 Å | 550 Å |
| R | 1800 | 2700 | >1000 Å | >2500 Å |
| Compara- | | | | |
| tive | | | | |

As seen from these data, presence of 2-AMPM activator in AF solutions results in increased copper removal rate; RR becomes high enough to provide sufficient wafer throughput even at low downforce. The activator drastically reduced dishing of copper lines during copper residue clearing and overpolishing step.

Data on selectivity of AF solution Q toward Ta and TaN (that are state-of-the-art barrier materials in copper damascene structures) are presented in Table 5.

TABLE 5
Abrasive-free Solution Q: Removal Rates
for Copper And Barrier Materials

| RR, Å/min | 2.5 psi Downforce | 1.5 psi Downforce |
|---|---|---|
| Cu | 3015 | 2640 |
| Ta | 15 | 10 |
| TaN | 28 | 11 |

As seen from these data, selectivity of the AF solution Q determined as a ratio of RR Cu:RR Ta or RR Cu:RR TaN, is higher than 200:1 at low polishing downforce.

Therefore, the AF polishing solutions of the present invention provide low dishing of copper lines with wide overpolish window and high selectivity toward barrier material.

Another advantage of the AF solutions of the present invention is their ability to provide complete copper clearing: no copper residue was observed in the field regions on wide line arrays (50 micron×50 micron) and high density features (9 micron×1 micron) after 25% overpolish time, while for low density features (1 micron×9 micron) with 50% overpolish time complete copper residue removal has been observed.

While the invention has been described in detail with reference to specific embodiments thereof, it will become apparent to one skilled in the art that various changes and modifications can be make, and equivalents employed, without departing from the scope of the appended claims.

What is claimed is:

1. An aqueous solution/slurry composition for polishing/planarization of substrates and layers, comprising:
a multifunctional activator that accelerates polishing removal while not increasing isotropic chemical etch, wherein said multifunctional activator is a diazine compound selected from the group consisting of pyridazine, pyrimidine, pyrazine, methylpyrimidines, aminopyrimidines, aminouracils, pyrazinecarboxamide, benzodiazines and derivatives thereof.

2. The aqueous solution/slurry of claim 1, wherein said multifunctional activator is a pyrimidine selected from the group consisting of 2-aminopyrimidine, 4-aminopyrimidine, 2,4-diaminopyrimidine, 4,6-diaminopyrimidine, 2,4,6-triaminopyrimidine, 4,5,6-triaminopyrimidine and derivatives thereof.

3. The aqueous solution/slurry of claim 1, further comprising abrasive particles in an amount of 0.01 to about 30 weight percent.

4. The aqueous solution/slurry of claim 3, wherein the abrasive particles are selected from the group consisting of colloidal and fumed silica, alumina, cerium dioxide, and mixtures thereof.

5. The aqueous solution/slurry of claim 4, wherein the abrasive particles are about 10-200 nm in size.

6. An aqueous solution/slurry composition for polishing/planarization of a metal layer, comprising:
a multifunctional activator that accelerates polishing removal while not increasing isotropic chemical etch, wherein said multifunctional activator is a diazine compound selected from the group consisting of pyridazine, pyrimidine, pyrazine, methylpyrimidines, aminopyrimidines, aminouracils, pyrazinecarboxamide, benzodiazines and derivatives thereof;
a corrosion inhibitor;
an oxidizer;
a complexing agent, said complexing agent being capable of forming water-soluble complexes with ions of a polished metal.

7. The aqueous solution/slurry of claim 6, wherein said multifunctional activator is a pyrimidine selected from the group consisting of 2-aminopyrimidine, 4-aminopyrimidine, 2,4-diaminopyrimidine, 4,6-diaminopyrimidine, 2,4,6-triaminopyrimidine, 4,5,6-triaminopyrimidine and derivatives thereof.

8. The aqueous solution/slurry of claim 6, further comprising abrasive particles in an amount of 0.01 to about 30 weight percent.

9. The aqueous solution/slurry of claim 6, wherein the complexing agent is selected from the group consisting of carboxylic acids, aminoacids, amidosulfuric acids, their respective derivatives, salts and mixtures thereof.

10. The aqueous solution/slurry of claim 6, wherein the oxidizer is selected from the group consisting of hydrogen peroxide, inorganic peroxy compounds and their salts, organic peroxides, compounds containing an element in the highest oxidation state and combinations thereof.

11. The aqueous solution/slurry of claim 8, wherein the abrasive particles are selected from the group of colloidal and fumed silica, alumina, cerium dioxide, and mixtures thereof.

12. The aqueous solution/slurry of claim 8, wherein the abrasive particles are about 10-200 nm in size.

13. The aqueous solution/slurry of claim 6, wherein the pH of the solution/slurry is below 6.0.

14. The aqueous solution/slurry of claim 11, wherein the abrasive particles are colloidal particles of silicon dioxide, wherein the colloidal silicon dioxide particles are anionically modified/doped with metallate anions selected from the group consisting of aluminate, stannate, zincate and plumbate, thereby providing a high negative surface charge to the abrasive particles and enhances the stability of the solution/slurry.

15. The aqueous solution/slurry of claim 14, wherein the slurry is acidic, and the silicon dioxide colloidal particles are modified/doped with aluminate anions, wherein their Zeta potential is −10 mV or less.

16. The aqueous solution/slurry of claim 6, further comprising: biocides, pH buffers, wetting agents, surface active additives and viscosity modifiers.

17. The aqueous solution/slurry composition of claim 6, wherein the solution/slurry is employed in copper interconnect structures in a chemical mechanical polishing/planarization process.

18. The aqueous solution/slurry composition of claim 17, the solution/slurry comprising:
a multifunctional activator in an amount of about 0.01 to about 10.0 weight percent, wherein the multifunctional activator is a pyrimidine selected from the group consisting of 2-aminopyrimidine, 4-aminopyrimidine, 2,4-diaminopyrimidine, 4,6-diaminopyrimidine, 2,4,6-triaminopyrimidine, 4,5,6-triaminopyrimidine and derivatives thereof;
a complexing agent in an amount of about 0.05 to 5.0 weight percent, wherein the complexing agent is capable of forming water-soluble complexes with copper ions;
an oxidizer in an amount of 0.1 to about 20 weight percent, wherein the oxidizer is selected from the group consisting of hydrogen peroxide, inorganic peroxy compounds and their salts, organic peroxides, compounds containing an element in the highest oxidation state and combinations thereof;
a corrosion inhibitor in an amount of 0.01 to about 1.0 weight percent, wherein the corrosion inhibitor is selected from the group consisting of imidazole, triazole, benzimidazole, benzotriazole, derivatives and mixtures thereof.

19. The aqueous solution/slurry of claim 18, further comprising: biocides, pH buffers, wetting agents, surface active additives and viscosity modifiers.

20. The aqueous solution/slurry of claim 18, wherein the pH of the solution/slurry is below 6.0.

21. The aqueous solution/slurry of claim 18, wherein the solution/slurry is acidic and abrasive-free.

22. The aqueous solution/slurry of claim 18, further comprising abrasive particles in an amount of 0.01 to about 30 weight percent, wherein the abrasive particles are about 10-200 nm in size.

23. The aqueous solution/slurry of claim 22, wherein the abrasive particles are colloidal particles of silicon dioxide, wherein the colloidal silicon dioxide particles are anionically modified/doped with metallate anions selected from the group consisting of aluminate, stannate, zincate and plumbate, thereby providing a high negative surface charge to the abrasive particles and enhances the stability of the solution/slurry.

24. The aqueous solution/slurry of claim 23, wherein the slurry is acidic, and the silicon dioxide colloidal particles are modified/doped with aluminate anions wherein their Zeta potential is −10 mV or less.

25. The aqueous solution/slurry of claim 18, wherein ratio of copper removal rate to copper chemical etch rate is at least 100:1.

26. A method of chemical mechanical polishing of a copper damascene structure, comprising:
supplying an aqueous polishing solution/slurry at a polishing interface between the polishing pad and the copper damascene structure, and polishing the structure, said aqueous solution/slurry comprising a multifunctional activator in an amount of about 0.01 to about 10.0 weight percent, a complexing agent in an amount of about 0.05 to 5.0 weight percent, an oxidizer in an amount of 0.1 to about 20 volume percent, and a corrosion inhibitor in an amount of 0.01 to about 1.0 weight percent.

27. The chemical mechanical polishing method of claim 26, wherein the copper removal rate to chemical etch ratio is at least 100:1.

28. The chemical mechanical polishing method of claim 26, further comprising:
selectively polishing a tantalum nitride/tantalum barrier material in preference to copper at a selectivity above 200.

29. The chemical mechanical polishing method of claim 26, wherein the multifunctional activator is a pyrimidine selected from the group consisting of 2-aminopyrimidine, 4-aminopyrimidine, 2,4-diaminopyrimidine, 4,6-diaminopyrimidine, 2,4,6-triaminopyrimidine, 4,5,6-triaminopyrimidine and derivatives thereof.

30. The chemical mechanical polishing method of claim 26, wherein said aqueous solution/slurry further comprises abrasive particles in an amount of 0.01 to about 30 weight percent.

31. The chemical mechanical polishing method of claim 26, wherein the aqueous solution/slurry is acidic and further comprises silicon dioxide colloidal particles that are modified/doped with aluminate anions.

32. A method of making an aqueous slurry solution for polishing/planarization of substrates and metal layers on multilevel interconnects, comprising:
providing a multifunctional activator in an amount of about 0.01 to about 10.0 weight percent, a complexing agent in an amount of about 0.05 to 5.0 weight percent, an oxidizer in an amount of 0.1 to about 20 volume percent, and a corrosion inhibitor in an amount of 0.01 to about 1.0 weight percent.

33. The method of making an aqueous slurry solution of claim 32, further comprising: biocides, pH buffers, wetting agents, surface active additives, and viscosity modifiers.
